(19) United States
(12) Patent Application Publication
(10) Pub. No.: US 2011/0240002 A1
(43) Pub. Date: Oct. 6, 2011

(54) CUTTING FLUID COMPOSITION FOR WIRESAWING

(75) Inventors: Steven Grumbine, Aurora, IL (US); Nevin Naguib Sant, Aurora, IL (US)

(73) Assignee: Cabot Microelectronics Corporation, Aurora, IL (US)

(21) Appl. No.: 13/139,046

(22) PCT Filed: Dec. 21, 2009
(86) PCT No.: PCT/US2009/068934

§ 371 Date: Jun. 10, 2011

Related U.S. Application Data
(60) Provisional application No. 61/203,143, filed on Dec. 20, 2008.

(51) Int. Cl. C09K 3/14; C09K 13/00; H01L 21/304; B28D 5/00; B28D 1/08

(52) U.S. Cl. 125/21; 252/79.1; 51/307; 51/303; 51/309; 51/298

(57) ABSTRACT

The present invention provides an aqueous wiresaw cutting fluid composition that reduces the amount of hydrogen produced during a wiresaw cutting process. The composition is comprised of an aqueous carrier, a particulate abrasive, a thickening agent, and a hydrogen suppression agent.

### CROSS-REFERENCE TO RELATED APPLICATIONS

This application claims the benefit of U.S. Provisional Application for Patent Ser. No. 61/203,143, filed on Dec. 20, 2008, which is incorporated herein by reference.

### FIELD OF THE INVENTION

This invention relates to slurry compositions used during a wiresaw cutting process. More particularly, this invention relates to aqueous wiresaw cutting fluid compositions that minimize the creation of hydrogen gas during a wiresaw cutting process.

### BACKGROUND OF THE INVENTION

Wiresaw cutting is the dominant method for making thin wafers for use in the integrated circuits and photo-voltaics (PV) industries. This method is also commonly used for wafering substrates of other materials, such as sapphire, silicon carbide, or ceramic substrates. A wiresaw typically has a web of fine metal wires, or a wireweb, where the individual wires have a diameter of around 0.15 mm and are arranged parallel to each other, at a distance of 0.1 to 1.0 mm, through a series of spools, pulleys and wire guides. Slicing, or cutting, is accomplished by contacting the workpiece (e.g. a substrate) with a moving wire to which an abrasive slurry has been applied.

Conventional wiresaw cutting fluid compositions or slurries typically comprise a carrier and abrasive particles combined by mixing in a ratio of about 1:1 by weight. The abrasive typically consists of a hard material such as silicon carbide particles. The carrier is a liquid that provides lubrication and cooling and also holds the abrasive to the wire so that the abrasive can contact the workpiece being cut.

The carrier can be a non-aqueous substance such as mineral oil, kerosene, polyethylene glycol, polypropylene glycol or other polyalkylene glycols. Non-aqueous carriers can have several disadvantages, however. For example, non-aqueous carriers can have limited shelf-life because of colloidal instability, and also can exhibit poor heat transfer characteristics. As such, water-based carriers are also used for wiresaw cutting processes.

Aqueous carriers also have certain known disadvantages. For example, during the wiresaw cutting process, a portion of the material being cut is removed. This material, called kerf, gradually accumulates in the cutting fluid slurry. In the process of wiresawing silicon and other water-oxidizable substrates, the kerf can become oxidized by oxygen or water. In an aqueous slurry, oxidation of a water-oxidizable workpiece by water produces hydrogen. The presence of hydrogen in the cutting fluid composition can disrupt the slurry distribution on the wire web (e.g., due to bubble formation) and reduce the cutting performance of the wiresaw. The creation of hydrogen can also be hazardous in a manufacturing environment (e.g., as an explosion hazard).

Accordingly, it would be advantageous to formulate an aqueous wiresaw cutting fluid composition that limits the amount of hydrogen created during a wiresaw cutting process. The compositions of the present invention fulfill this need.

### BRIEF SUMMARY OF THE INVENTION

The present invention provides an aqueous wiresaw cutting fluid composition that reduces the amount of hydrogen produced when cutting water-reactive work pieces such as silicon during a wiresaw cutting process. The composition comprises an aqueous carrier, a particulate abrasive, a thickening agent, and a hydrogen suppression agent. The abrasive, the thickening agent, and the hydrogen suppressing agent are each separate and distinct components of the cutting fluid compositions of the present invention, as is the aqueous carrier; although, each of these components may have more than one function or provide more than one benefit to the wiresaw cutting performance of the composition.

While not wishing to be bound by theory, it is believed that the hydrogen suppressing agent reacts with molecular hydrogen to trap the gas or chemically react with the hydrogen gas thereby reducing the amount of free hydrogen gas that is present in the composition. Suitable hydrogen suppressing agents include hydrophilic polymers, surfactants, silicone, and hydrogen scavengers.

One embodiment of the present invention is an aqueous wiresaw cutting fluid composition. Included in this composition is an aqueous carrier containing a thickening agent, a particulate abrasive, and a hydrogen suppressing agent. The hydrogen suppression agent is selected from a group consisting of a hydrophilic polymer, a surfactant having a hydrophobic portion comprising at least 6 carbon atoms in a chain, a silicone, and a hydrogen scavenger.

Another embodiment of the present invention is an aqueous wiresaw cutting fluid composition comprising a particulate abrasive, an aqueous carrier, a thickening agent, and at least one hydrogen suppressing agent selected from the group consisting of a surfactant, a hydrogen-reactive metal compound, a silicon-reactive metal compound, a hydrosilylation catalyst, and an organic electron transfer agent. The surfactant comprises a hydrophobic portion and a hydrophilic portion. The hydrophobic portion of the surfactant comprises one or more of a substituted hydrocarbon group, a non-substituted hydrocarbon group, and a silicone group. The hydrophilic portion of the surfactant comprises one or more of a polyoxyalkylene group, an ether group, an alcohol group, an amino group, a salt of an amino group, an acidic group, and a salt of an acidic group.

Another embodiment of the present invention is an aqueous wiresaw cutting fluid composition comprising an aqueous carrier containing a thickening agent, a particulate abrasive, and a hydrogen suppressing agent selected from a nonionic surfactant having an HLB of about 18 or less, and a hydrophilic polymer having an HLB of about 18 or less.

According to additional teachings of the present invention, hydrogen generation in a wire saw cutting process is ameliorated by utilizing an aqueous wiresaw cutting fluid of the type taught herein while cutting a workpiece with a wiresaw.

In certain preferred embodiments of the present invention, the composition has an acidic pH. While not wishing to be bound by theory, it is believed that decreasing the pH of the composition decreases the rate of any oxidation reaction that might occur between water and the material being cut during the wiresaw process. Reducing the rate of the oxidation reaction reduces the amount of hydrogen that is produced by such a reaction. In other particularly preferred embodiments, the cutting fluid composition comprises a combination of a surfactant and a hydrophilic polymer, a combination of a surfactant and a silicone, or a combination of a surfactant, a hydrophilic polymer, and a silicone as the hydrogen suppressing agent.

### DETAILED DESCRIPTION OF THE INVENTION

The compositions of the present invention each contain an aqueous carrier such as water, an aqueous glycol and/or an aqueous alcohol. Preferably, the aqueous carrier predominately comprises water. The aqueous carrier preferably comprises about 1 to about 99 percent of the composition by weight, more preferably about 50 to about 99 percent by weight. Water preferably comprises about 65 to about 99 percent by weight of the carrier, more preferably about 80 to about 98 percent by weight.

The compositions of the present invention also each contain a particulate abrasive such as silicon carbide, diamond, or boron carbide. The particulate abrasive typically comprises about 1 to about 60 percent by weight of the composition. In some embodiments, the particulate abrasive comprises particulate diamond present at a concentration of about 1 to about 10 percent by weight. In another embodiment when the abrasive is not diamond it is preferred that the particulate abrasive comprises about 30 to about 60 percent by weight of the composition Abrasives suitable for use in wiresaw cutting fluids are well known in the art.

Relatively large amounts of hydrogen are formed when a water-oxidizable material (e.g., silicon) is cut using compositions containing only water in a wiresaw cutting process. For example, using the process described in Example 1, simulated wiresaw cutting of a silicon wafer with solely water as the cutting fluid resulted in the generation of hydrogen at the rate of about 1.79 milliliters-per-min (mL/min) during the wiresaw cutting process. Example 2 shows that as the water content of the aqueous carrier increases, the hydrogen generation rate also increases, to a maximum at 100% water. To reduce the hydrogen generation rate during the wiresaw cutting process, the compositions of the present invention each contain additional components to reduce the hydrogen generating potential of the composition.

The compositions of the present invention each contain a thickening agent such as a clay, a gum, a cellulose compound (including hydroxypropylcellulose, methylcellulose, hydroxyethylcellulose), a polycarboxylate, a poly(alkylene oxide) and the like. The thickening agent can comprise any material that is water-soluble, water-swellable, or water-dispersible, and which provides a Brookfield viscosity for the carrier in the range of at least 40 centiPoise (cP) at a temperature of about 25° C. It is most preferred that the thickening agent provides a Brookfield viscosity for the carrier of about 40 to about 120 cps. The thickening agent is present in the composition at a concentration in the range of about 0.2 percent to about 10 percent by weight. The thickening agent is a separate and distinct component of the composition. As used herein, the term “thickening agent” encompasses a single material or a combination of two or more materials, and refers to the component or components of the composition that provide the majority of the viscosity of the composition, excluding any viscosity provided by the abrasive.

Preferred thickening agents are nonionic polymeric thickeners such as cellulose compounds (e.g., hydroxypropylcellulose, methylcellulose, hydroxyethylcellulose), or poly(alkylene oxide) materials (e.g., a poly(ethylene glycol), an ethylene oxide-propylene oxide copolymer, and the like). Preferably, the thickening agent has a weight average molecular weight of greater than about 20,000 Daltons (Da), more preferably at least about 50,000 Da (e.g., about 50,000 to about 150,000 Da), since lower molecular weight materials tend to be less efficient as thickeners.

While not wishing to be bound by theory, it is believed that a thickening agent of the type described herein associates with the surface of the workpiece and kerf and thereby reduces the amount of water that can contact these surfaces. This reduction in the amount of workpiece surface contacted by water reduces the oxidation of the workpiece surface by water, which in turn reduces the hydrogen generation rate.

The compositions of the present invention each contain one or more hydrogen suppressing agents. Suitable hydrogen suppressing agents include hydrophilic polymers, surfactants, silicones, and various hydrogen scavengers, such as hydrogen-reactive metal compounds, silicon reactive metal compounds, hydrosilylation catalysts, and organic electron-transfer agents. The compositions of the present invention can contain one of the types of hydrogen suppressing agents listed, or a combination of one or more of these types of hydrogen suppressing agents. While the thickening agent component of the composition may itself provide some hydrogen suppressing activity, the composition also includes a separate hydrogen suppressing agent that is distinct from the thickening agent.

The surfactants used in the present invention have at least a hydrophobic portion, and a hydrophilic portion. Suitable surfactant types that can be added to the composition of the present invention include an aryl alkoxylate, an alkyl alkoxylate, an alkoxylated silicone, an acetylenic alcohol, an ethoxylated acetylenic diol, a C₈ to C₂₂ alkyl sulfate ester, C₈ to _{C22} alkyl phosphate ester, C₈ to C₂₂ alcohol, an alkyl ester, alkylaryl ethoxylates, ethoxylated silicones (e.g., dimethicone copolyols), acetylenic compounds (e.g. acetylenic alcohols, ethoxylated acetylenic diols), fatty alcohol alkoxylates, C₆ and greater fluorinated compounds, C₆ to C₂₂ alkyl sulfate ester salts, C₆ to C₂₂ alkyl phosphate ester salts, and C₈ to C₂₂ alcohols. A combination of one or more of these surfactant types can be added to the composition of the present invention to reduce the generation of hydrogen.

Non-limiting examples of suitable surfactants include alkyl sulfates such as sodium dodecyl sulfate; ethoxylated alkyl phenols such as nonylphenol ethoxylate; ethoxylated acetylenic diols such as SURFYNOL® 420, available from Air Products and Chemicals, Inc.; ethoxylated silicones, such as the SILWET® brand surfactants available from Momentive Performance Materials; alkyl phosphate surfactants such as DEPHOS® brand surfactants available from DeFOREST Enterprises; C₈ to C₂₂ alcohols, such as octanol, and 2-hexyl-1-decanol; and the like. Surfactants can be added to the composition of the present invention at a concentration in the range of about 0.01 wt. % or greater based on the weight of the liquid carrier (e.g., at least about 0.1 wt. %, at least about 0.5 wt. %, at least about 1 wt. %, or at least about 2 wt. % surfactant). Alternatively, or in addition, the liquid carrier can comprise about 20 wt. % or less surfactant (e.g., about 10 wt. % or less, about 5 wt. % or less, about 3 wt. % or less surfactant). Thus, the liquid carrier can comprise an amount of surfactant bounded by any two of the above endpoints. For example, the liquid carrier can comprise about 0.01 wt. % surfactant to about 20 wt. % surfactant (e.g., about 0.1 wt. % to about 10 wt. %, about 0.5 wt. % to about 3 wt. % surfactant).

Preferably, the hydrophobic portion of the surfactant comprises one or more of a substituted hydrocarbon group, a non-substituted hydrocarbon group, and a silicon containing group. Preferably, the hydrophobic portion of the surfactant comprises at least one hydrocarbon group containing at least 6 carbon atoms in a chain and most preferred the hydrophobic portion of the surfactant comprises at least one hydrocarbon group containing at least 8 non-aromatic carbon atoms in a chain. The hydrophilic portion of the surfactant preferably comprises one or more of a polyoxyalkylene group, an ether group, an alcohol group, an amino group group, and a salt of an amino group, an acidic group, and a salt of an acidic group.

Nonionic surfactants having a hydrophilic-lipophilic balance (HLB) value of about 20 or less, and preferably about 18 or less, are particularly suitable to reduce the hydrogen generation rate in the compositions of the present invention. In some preferred embodiments, nonionic surfactant has an HLB of about 15 or less, preferably about 10 or less. Nonionic surfactants can be added to the composition of the present invention at a concentration in the range of about 0.01 percent to about 4 percent by weight of the composition.

Hydrophilic polymers suitable for use in the present compositions include a polyether, such as a poly(ethylene glycol), a poly(propylene glycol), an ethylene glycol-propylene glycol copolymer, and the like. Preferred hydrophilic polymers are polypropylene glycol or copolymers comprising a polyether. Preferably, the hydrophilic polymers have an HLB of about 18 or less and most preferably an HLB of about 12 or less.

Hydrophilic polymers can be added to the composition of the present invention at a concentration in the range of about 0.01 wt. % based on the weight of the liquid carrier (e.g., at least about 0.1 wt. %, at least about 0.5 wt. %, at least about 1 wt. %, or at least about 2 wt. % surfactant). Alternatively, or in addition, the liquid carrier can comprise about 20 wt. % or less hydrophilic polymer (e.g., about 10 wt. % or less, about 5 wt. % or less, about 3 wt. % or less hydrophilic polymer). Thus, the liquid carrier can comprise an amount of hydrophilic polymer bounded by any two of the above endpoints. For example, the liquid carrier can comprise about 0.01 wt. % hydrophilic polymer to about 20 wt. % hydrophilic polymer (e.g., about 0.1 wt. % to about 10 wt. %, about 0.5 wt. % to about 3 wt. % hydrophilic polymer).

While not wishing to be bound by theory, it is believed that surfactants associate with the surface of the workpiece and/or kerf and thereby reduces the amount of water that can contact these surfaces.

A silicone also can be added to the compositions of the present invention to reduce hydrogen generation. Suitable silicones include polydimethicones (i.e., dimethylsiloxane polymers) such as SEDGEKIL® MF-3 and SEDGEKIL® GGD commercially available from Omnova Solutions, Inc. The silicone can be added to the composition of the present invention at a concentration in the range of about 0.01 percent to about 4 percent by weight of the composition.

In addition, an acidic substance suitable to lower the pH of the composition can be added to reduce hydrogen generation. As is generally known in the art (see, e.g., “Oxidation of Silicon by Water,” J. European Ceramic Soc. 1989; 5:219-222 (1989)), lowering the pH of the composition slows the rate of oxidation of the material being cut. Slowing the oxidation reaction in turn reduces the amount of hydrogen generated during the wiresaw cutting process. Suitable acidic substances include mineral acids (e.g., hydrochloric acid, sulfuric acid, phosphoric acid, nitric acid, and the like) and organic acids (e.g., a carboxylic acid such as acetic acid, citric acid, and succinic acid; an organophosphonic acid; an organosulfonic acid; and the like).

In some embodiments of the present invention, an oxidizing agent is added to the composition to reduce hydrogen generation. An oxidizing agent can be added to the composition of the present invention in an amount of about 0.01 to about 4% by weight. The oxidizing agent can compete with water to oxidize the material being cut (such as silicon). In addition or alternatively, the oxidizing agent may oxidize any hydrogen generated during cutting of the workpiece, to form water.

Likewise, a hydrogen scavenger such as a hydrogen-reactive metal compound or silicon-reactive metal compound (e.g., a Pt, Pd, Rh, Ru or Cu metals, such as a carbon or diatomaceous earth-supported metal, inorganic salts of such metals, or organometallic salts of such metals), a hydrosilylation catalyst (e.g., inorganic or organometallic Pt, Pd, Rh, Ru, or Cu salts), organic electron transfer agent (e.g., quinones, TEMPO, or other radical forming compounds), can be added to the compositions of the present invention. The compositions of the present invention can contain one of the types of hydrogen scavengers listed, or a combination of one or more of these types of hydrogen scavengers. Hydrogen scavengers can be added to the composition of the present invention at a concentration in the range of about 0.01 percent to about 4 percent by weight of the composition. Not wishing to be bound by theory, it is believed that the hydrogen scavenger binds to or otherwise reacts with hydrogen and reduces the amount of free hydrogen released during the wiresaw cutting process.

It is preferred that the hydrogen suppressing agent does not cause excessive foaming during use. Foaming potential can be evaluated by bubbling air through the carrier and determining the height of foam after a set period of time. It is preferred that the foaming observed in the presence of the hydrogen suppressing agent is about equal to or less than the foaming with the thickener alone. It is more preferred that the foaming with the hydrogen suppressing agent is less than the foaming observed with the thickener alone (e.g., at least about 10% less, at least about 50% less, at least about 80% less, at least about 95% less). It is most preferred that the hydrogen suppressing agent does not cause any more foam than the thickener alone, and that the hydrogen suppressing agent does not contain silicon.

Other commonly used additives including biocides (e.g., an isothiazoline biocide), defoaming agents, dispersants, and the like, can be added to the compositions of the present invention, if desired to provide a particular property or characteristic to the composition. Such additives are well known in the art.

The compositions of the invention reduce the amount of hydrogen generated during the wiresaw cutting of a water oxidizable material such as silicon. In some preferred embodiments of the present invention, the hydrogen generation rate is reduced from about 1.8 mL/min for a general aqueous wiresaw cutting fluid composition to a rate below about 0.75 mL/min. In some particularly preferred embodiments discussed below, the hydrogen generation rate is reduced to a range of about 0.01 to 0.3 mL/min. Preferably, the compositions of the present invention reduce the rate of hydrogen generation by at least about 40 percent (e.g., at least about 60%, at least about 80%, at least about 95%) over the amount of hydrogen generated when no hydrogen suppressing agent is used. The following examples further illustrate the invention but, of course, should not be construed as in any way limiting its scope.

### Example 1

A general procedure was used to simulate the chemical environment of the wirecutting process and measure the hydrogen generation rates of the compositions of the invention. The compositions used in this general procedure contain water and various additives, with the abrasive being supplied as a separate component (i.e., zirconia milling beads).

In this example, powdered Si was reacted with various compositions in a flask attached to a gas collector. The hydrogen generated during the process was collected and volumetrically measured.

Specifically, a round bottom flask fitted with a tubing adapter, a magnetic stir bar and a septum inlet was placed in a water bath on a magnetic stirring hot plate. The temperature of the water bath was controlled to about 55 degrees Celsius. About 25 grams of 0.65 mm diameter zirconia milling beads obtained from Toray Industries, Inc. and about 25 grams of the composition to be tested were added to the flask, and the flask was purged with nitrogen. Separately, about 100 grams of 0.65 mm diameter zirconia milling beads and about 6.2 grams of pure silicon powder having a particle diameter of about 1-5 μm were mixed at about 1600 rpm for 5 min under a nitrogen atmosphere using a high speed mixer (SPEEDMIXER® Model No. DAC150 FVZ-K obtained from Flacktek Inc.) to further mill the silicon. The freshly milled silicon was rapidly transferred to the flask containing the composition to be tested, and the flask was purged with nitrogen while being stirred at about 300 rpm. Hydrogen formed by reaction of the silicon with water in the composition was collected and volumetrically measured. The hydrogen generation rate was calculated by dividing the volume of hydrogen generated by the period of time the milled silicon was stirred. The milled silicon was stirred from about 60 minutes to about 180 minutes before calculating hydrogen generation rate.

### Example 2

Using the general procedure of Example 1, the hydrogen generation rate of seven compositions having various water concentrations were measured. The compositions contained varying ratios of deionized water and poly(ethylene glycol). The hydrogen generation rate of each composition is shown below in Table 1. This example demonstrates that as the concentration of water in the composition increases, the hydrogen generation rate also increases, confirming the observation that conventional relatively high-water-content cutting fluids tend to have hydrogen generation problems.

TABLE 1
Water Content of Composition and Hydrogen Generation Rate

| Percent | Percent | Hydrogen |
|---|---|---|
| Deionized | Polyethylene | Generation |
| Water | Glycol | Rate (mL/min) |
| 100 | 0 | 1.79 |
| 75 | 25 | 1.25 |
| 65 | 35 | 1.19 |
| 58 | 42 | 0.94 |
| 50 | 50 | 0.28 |
| 25 | 75 | 0.05 |
| 5 | 95 | 0.011 |

### Example 3

Using the general procedure of Example 1, the hydrogen generation rate was measured of an aqueous composition containing about 4% by weight of hydroxyethylcellulose thickener and about 500 ppm of an isothiazolinone biocide. The hydrogen generation rate of this composition was 0.71 mL/min.

### Example 4

Using the general procedure of Example 1, the hydrogen generation rate was measured for aqueous compositions similar to those described in Example 3, containing about 4% by weight of hydroxyethylcellulose, about 500 ppm of an isothiazolinone biocide, as well as varying amounts of an ethoxylated acetylenic diol surfactant (i.e., as a hydrogen suppressing agent) sold commercially as SURFYNOL® 420, which is 4,7-dihydroxy-2,4,7,9-tetramethyldec-5-yne that is partially ethoxylated and averages about 1.3 mole of ethylene oxide per mole of the acetylenic diol. The amount of SURFYNOL® 420 in each composition, and the observed hydrogen generation rate obtained therewith are shown in Table 2. The compositions were relatively neutral in pH unless otherwise noted. As the data in Table 2 clearly indicate, the presence of the surfactant and acidic pH both tend to beneficially and surprisingly lower the hydrogen generation rate.

TABLE 2
Hydrogen Generation Rate of Compositions containing SURFYNOL 420

| Surfactant | Other Additives | Additional | Hydrogen |
|---|---|---|---|
| (Percent | (Percent | Composition | Generation |
| by Weight) | by Weight) | Characteristics | Rate (mL/min) |
| 0.3% SURFYNOL | | | 0.13 |
| 420 | | | |
| 0.3% SURFYNOL | | pH 4 | 0.11 |
| 420 | | | |
| 0.3% SURFYNOL | 0.5% Aluminum | pH 4 | 0.07 |
| 420 | Nitrate | | |
| 0.5% SURFYNOL | 4% Poly(ethylene | | 0.05 |
| 420 | glycol) | | |

### Example 5

Using the general procedure of Example 1, the hydrogen generation rate was measured for aqueous compositions similar to those described in Example 3, containing about 4% by weight of hydroxyethylcellulose, about 500 ppm of an isothiazolinone biocide, as well as various hydrogen suppressing additives. The identity and amount of the additives in the compositions, and the corresponding observed hydrogen generation rate are shown in Table 3. The surfactant SILWET® 1-7210, used in the examples, is an ethoxylated polydimethylsiloxane (i.e., a dimethicone copolyol) commercially available from Momentive Performance Materials. SAGTEX® brand silicone is a polydimethylsiloxane (i.e., a polydimethicone) emulsion available from Momentive Performance Materials. SEDGEKIL® brand silicone is a defoamer commercially available from Omnova Solutions, Inc. DEPHOS® 8028 is an active potassium salt of an alkyl phosphate ester commercially available from DeFOREST Enterprises. As is evident in the data in Table 3, The presence of a surfactant such as nonionic alkylaryl ethoxylate, an ethoxylated silicone, a C₈ to C₂₂ alcohol, an alkyl sulfate ester or an alkyl phosphate ester, is surprisingly effective at reducing hydrogen generation rates. The combination of a silicone with the surfactant is even more effective.

TABLE 3
Hydrogen Generation Rate of Compositions Containing Various Additives

| | | Additional | Hydrogen |
|---|---|---|---|
| Additive | | Composition | Generation |
| (amount) | Additive Type | Characteristics | Rate (mL/min) |
| SEDGEKIL ® | Silicone | | 0.75 |
| (70 ppm) | | | |
| SEDGEKIL 1 ® | Silicone; | | 0.77 |
| (70 ppm), | Hydrophilic | | |
| Poly(ethylene | polymer | | |
| glycol) (4%) | | | |
| SEDGEKIL ® | Silicone | pH 3 | 0.29 |
| (70 ppm) | | | |
| SEDGEKIL ® | Silicone; | HLB value = 7 | 0.19 |
| (0.3%), SILWET 1- | Nonionic silicone | | |
| 7210 ® (0.3%) | surfactant | | |
| SAGTEX ® (0.5%) | Silicone | | 0.48 |
| SAGTEX ® | Silicone; | HLB value = 7 | 0.19 |
| (0.3%), SILWET 1- | Nonionic silicone | | |
| 7602 ® (0.3%) | surfactant | | |
| SAGTEX ® | Silicone; | HLB value = 15 | 0.15 |
| (0.5%), SILWET 1- | Nonionic silicone | | |
| 7604 ® (0.3%) | surfactant | | |
| SEDGEKIL ® | Silicone; | | 0.19 |
| (70 ppm), | Hydrophilic | | |
| Poly(ethylene | polymer | | |
| glycol) (4%), | Anionic | | |
| DEPHOS ® 8028 | phosphate | | |
| (0.1%) | surfactant | | |
| SAGTEX ® | Silicone; | | 0.11 |
| (0.5%), sodium | Anionic sulfate | | |
| dodecyl sulfate | surfactant | | |
| (0.5%) | | | |
| 2-hexyl-1-decanol | High Molecular | | 0.45 |
| (0.5%) | Weight Alcohol | | |
| Octanol (0.3%) | High Molecular | HLB value = 5 | 0.57 |
| | Weight Alcohol | | |
| Nonylphenol | Alkylaryl | HLB value = 18 | 0.29 |
| ethoxylate (0.3%) | ethoxylate | | |
| | surfactant | | |

### Example 6

A large scale cutting experiment was performed to further verify the results obtained during the experiments described in Examples 1 through 5 above. In particular, a silicon ingot having the dimensions 125 mm×125 mm×300 mm was cut using a Myer-Burger 261 wiresaw. The wiresaw was equipped with a wire having a diameter of about 120 μm and a length of about 315 km. The cutting process was performed using a wire speed of about 8 meters per second (m/sec), a wire tension of about 23 N, a wire guide pitch of about 400 μm, a feed rate of about 0.2 millimeters per minute (mm/minute), a slurry flow rate of about 5000 kilograms per hour (kg/hr), and a slurry temperature of about 25 degrees Celsius.

One aqueous composition used during the wiresaw cutting process comprised about 2% hydroxyethylcellulose thickener (product #WP09H from Dow Chemical Co.), about 6% poly(ethylene glycol) (hydrophilic polymer) having a molecular weight of about 300, 0.2% SURFYNOL® 420 surfactant, about 0.01% biocide (commercially available as KATHON® LX from Rohm & Haas), and about 50% silicon carbide abrasive (JIS 1200). The amount of hydrogen generation was measured visually by observing the amount of hydrogen bubbles that formed on the surface of the slurry tank during and after the wire-saw cutting process. Less than one monolayer of hydrogen bubbles formed on the surface of the slurry tank during the wirecutting process using this composition.

Another composition used during the wiresaw cutting process comprised about 2% hydroxyethyl cellulose thickener (product #WPO9H from Dow Chemical Co.), about 4% polyethylene glycol having a molecular weight of about 300, and about 50% silicon carbide abrasive (JIS 1200) (no surfactant present). A significant amount of hydrogen bubbles formed on the top of the slurry tank during the wire-saw cutting process using this composition. The high volume of hydrogen bubbles formed using this composition flowed over the sides of the slurry vessel. This volume of hydrogen bubbles was significantly larger than the volume of hydrogen formed using the composition discussed above. Accordingly, the data clearly indicate that a hydrogen suppressing agent comprising combination of a hydrophilic polymer and a surfactant provides surprising superior performance.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. An aqueous wiresaw cutting fluid composition comprising:
a particulate abrasive;
an aqueous carrier containing a thickening agent; and
at least one hydrogen suppressing agent selected from the group consisting of a hydrophilic polymer, a surfactant having a hydrophobic portion comprising at least 6 carbon atoms in a chain, a silicone, and a hydrogen scavenger;
wherein the abrasive, the thickening agent and the hydrogen suppressing agent are separate and distinct components of the composition.

2. The composition of claim 1, wherein the at least one hydrogen suppressing agent is the surfactant having a hydrophobic portion comprising at least 6 carbon atoms in a chain, wherein the surfactant has an HLB of 18 or less.

3. The composition of claim 1, wherein the at least one hydrogen suppressing agent is the hydrophilic polymer, wherein the polymer has an HLB of 18 or less.

4. The composition of claim 1 wherein the thickening agent comprises a cellulose compound.

5. The composition of claim 1 wherein the thickening agent provides a viscosity of at least 40 cP to the carrier.

6. The composition of claim 1 wherein the thickening agent is present at a concentration in the range of about 0.2 to about 10 percent by weight.

7. The composition of claim 1 wherein the abrasive comprises silicon carbide, diamond or boron carbide.

8. The composition of claim 1 comprising at least two hydrogen suppressing agents.

9. The composition of claim 1 wherein the abrasive is present at a concentration in the range of about 30 to about 60 percent by weight.

10. The composition of claim 1 wherein the surfactant is selected from the group consisting of an aryl alkoxylate, an alkyl alkoxylate, an alkoxylated silicone, an acetylenic alcohol, an ethoxylated acetylenic diol, a C₈ to C₂₂ alkyl sulfate ester, C₈ to C₂₂ alkyl phosphate ester, C₈ to C₂₂ alcohol, and an alkyl ester.

11. The composition of claim 1 wherein the composition comprises about 0.01 to about 4 percent by weight of a silicone.

12. The composition of claim 1 further comprising about 0.01 to about 4 percent by weight of an oxidizing agent.

13. The composition of claim 1 wherein the composition comprises about 0.01 to about 4 percent by weight of the hydrogen scavenger.

14. The composition of claim 13 wherein the hydrogen scavenger is selected from the group consisting of a hydrogen reactive metal compound, a hydrosilylation catalyst, an organic electron-transfer agent, and a silicon reactive metal compound.

15. An aqueous wiresaw cutting fluid composition comprising:
a particulate abrasive;
an aqueous carrier;
a thickening agent; and
at least one hydrogen suppressing agent selected from the group consisting of a surfactant, a hydrogen-reactive metal compound, a silicon-reactive metal compound, a hydrosilylation catalyst, and an organic electron transfer agent;
wherein the surfactant comprises a hydrophobic portion and a hydrophilic portion;
the hydrophobic portion of the surfactant comprising one or more of a substituted hydrocarbon group, a non-substituted hydrocarbon group, and a silicone group; and the hydrophilic portion of the surfactant comprises one or more of a polyoxyalkylene group, an ether group, an alcohol group, an amino group, a salt of an amino group, an acidic group, and a salt of an acidic group, and wherein the abrasive, the thickening agent and the hydrogen suppressing agent are separate and distinct components of the composition.

16. The composition of claim 15 wherein the abrasive comprises silicon carbide, diamond or boron carbide.

17. The composition of claim 15 wherein the hydrophilic portion of the surfactant comprises one or more ether groups.

18. The composition of claim 15 wherein the abrasive is present at a concentration in the range of about 30 to about 60 percent by weight.

19. A method of ameliorating hydrogen generation in a wiresaw cutting process utilizing an aqueous wiresaw cutting fluid, the method comprising cutting a workpiece with the wiresaw and an aqueous cutting fluid composition of claim 1.

20. The method of claim 19 wherein the workpiece comprises silicon.
